(19) United States
(12) Patent Application Publication
(10) Pub. No.: US 2026/0280338 A1
(43) Pub. Date: Sep. 17, 2026

(54) POWER DISTRIBUTION CABLE ASSET MANAGEMENT SYSTEM

(71) Applicant: LS CABLE & SYSTEM LTD., Anyang-si, Gyeonggi-do (KR)

(72) Inventors: Jung Ji KWON, Gumi-si, Gyeongsangbuk-do (KR); Hun Chul YANG, Yeonsu-gu, Incheon (KR); Ju Mi SEO, Gwacheon-si, Gyeonggi-do (KR); Dae Ung YONG, Anyang-si, Gyeonggi-do (KR); Won Young KIM, Dongdaemun-gu, Seoul (KR)

(21) Appl. No.: 19/168,918

(22) PCT Filed: Apr. 20, 2023
(86) PCT No.: PCT/KR2023/005338

§ 371 Date: Sep. 25, 2025

(30) Foreign Application Priority Data
Apr. 6, 2023 (KR) 10-2023-0045581

(51) Int. Cl. H02J 13/12; G01R 31/58; H02J 13/10

(52) U.S. Cl. CPC H02J 13/12; G01R 31/58; H02J 13/10

(57) ABSTRACT

The present disclosure relates to a power distribution cable asset management system. Specifically, the present disclosure relates to a power distribution cable asset management system which makes it possible to make efficient and accurate judgments about line diagnosis and replacement in a power distribution cable system.

### CROSS-REFERENCE TO RELATED APPLICATIONS

The present application is a National Stage of International Application No. PCT/KR2023/005338, filed on Apr. 20, 2023, which claims priority to Korean Application No. 10-2023-0045581, filed Apr. 6, 2023, the entire contents of each hereby incorporated by reference.

### FIELD

The present disclosure relates to a power distribution cable asset management system. Specifically, the present disclosure relates to a power distribution cable asset management system that enables efficient and accurate decision-making (judgments) regarding line diagnosis and replacement in a power distribution cable system.

### BACKGROUND

The power distribution cable is an important equipment that supplies electric power to large-scale industrial complexes and commercial buildings, and a lot of cost is required for facility recovery due to a failure of a facility while operating a power supply facility including the power distribution cable. Accordingly, a company that supplies electric power is making a lot of effort for maintenance in order to reduce recovery cost due to occurrence of a blackout accident and the like and a lot of cost is being used for the maintenance.

In particular, an electric power supply system through the power distribution cable has many lines due to its characteristics, and identification of a connection point of a cable at an intermediate position is difficult, and judgment of live line/dead line presence at an exposed part of the cable at the intermediate position is difficult, and information of various diagnosis histories and specific matters is not left as a record, so efficient and accurate decision-making (judgments) regarding line diagnosis, replacement, or the like is difficult.

Korean Patent Publication No. 10-2022-0050287 discloses a cable asset management system provided with a smart cable, a control unit, a management server, a sensor, and the like. However, the cable asset management system discloses only contents of storing and managing various information of a line detected or input by a sensor and the like and thereby simply managing inventory and lifespan of a cable, but does not disclose at all contents of whether the line is diagnosed from the corresponding information and whether replacement is efficiently and accurately judged.

Therefore, a power distribution cable asset management system that enables efficient and accurate decision-making (judgments) regarding line diagnosis and replacement in a power distribution cable system is urgently required.

### SUMMARY

The present disclosure is directed to providing a power distribution cable asset management system that enables efficient and accurate decision-making (judgments) regarding line diagnosis and replacement in a power distribution cable system.

To achieve the objects, the present disclosure is directed to providing
a power distribution cable asset management system, comprising: a management unit configured to store and manage information on a line including a power distribution cable; and a sensor unit configured to collect information from the line and transmits the collected information to the management unit, wherein the management unit calculates a line health index of the power distribution cable included in the line based on the information on the line.

Here, the management unit may comprise: a gateway configured to receive information on the line collected from the sensor unit; a data storage configured to store the information collected through the gateway; and an operation device configured to calculate a line health index of the power distribution cable included in the line from the information stored in the data storage.

In addition, the information stored in the data storage may comprise at least one selected from a group consisting of manufacturing process information of the power distribution cable, distribution process information of the power distribution cable, laying environment information of the power distribution cable, and operation environment information of the power distribution cable, in addition to the information collected through the gateway.

Further, the manufacturing process information may comprise at least one selected from a group consisting of product name of the power distribution cable, structure of the power distribution cable, allowable voltage of the power distribution cable, allowable transmission amount of the power distribution cable, allowable current of the power distribution cable, allowable temperature of the power distribution cable, total weight of the power distribution cable, specification of the power distribution cable, quantity of the power distribution cable, color of the power distribution cable, certification details of the power distribution cable, and manufacturing date of the power distribution cable, the distribution process information may comprise at least one selected from a group consisting of transport information of the power distribution cable, warehousing date of the power distribution cable, shipping date of the power distribution cable, supplier of the power distribution cable, presence of inventory of the power distribution cable, inventory amount of the power distribution cable, and inventory storage location information of the power distribution cable, the laying environment information may comprise at least one selected from a group consisting of a laying method of the power distribution cable, presence of a conduit of the power distribution cable, degree of bending of the power distribution cable, surrounding temperature of the power distribution cable, and surrounding humidity of the power distribution cable, and the operation environment information may comprise at least one selected from a group consisting of load characteristic of the line and failure rate of the line.

Further, the operation device may acquire statistics regarding replacement causes of one or more power distribution cables by line position by utilizing the information stored in the data storage as big data, set a weight by failure cause item according to frequency of failure causes of the power distribution cable based on the statistics, and obtain a line health index by calculating scores by replacement cause item of the one or more power distribution cables, then summing values obtained by multiplying the scores by the weights.

Here, the operation device may assign a line health grade as good, caution, warning, and serious in descending order of the line health index

Meanwhile, the sensor unit may comprise at least one selected from a group consisting of a temperature sensor, a current sensor, a PD (Partial Discharge) sensor, a leakage Current sensor, and a fire sensor.

In addition, the power distribution cable asset management system may further comprise a terminal unit configured to enable a manager to recognize a power distribution cable of the line and to view information stored and managed in the management unit regarding the recognized power distribution cable.

Here, the terminal unit may comprise: a scanner capable of scanning a pattern printed on a surface of the power distribution cable to identify the power distribution cable; an input device through which a manager inputs contents of offline diagnosis regarding the line; and a display displaying information on the power distribution cable scanned by the scanner and a line health index.

In addition, the power distribution cable may comprise a smart cable having a pattern printed on an outer surface thereof capable of identifying the power distribution cable.

Further, the information on the power distribution cable stored in the management unit may be automatically updated by receiving information from the sensor unit, or may be manually updated by the manager through the input device of the terminal unit, and when the manager scans the pattern with the scanner of the terminal unit, information on the power distribution cable recognized according to the scanned pattern may be provided from the management unit and displayed on the display of the terminal unit.

Further, the pattern may be printed with ultraviolet (UV) curing ink cured by ultraviolet irradiation, and forms a two-dimensional code.

The power distribution cable asset management system according to the present disclosure exhibits an excellent effect of enabling efficient and accurate decision-making (judgments) regarding line diagnosis, replacement, and the like from a line health index calculated by calculating the line health index according to weight of various information on a line.

### BRIEF DESCRIPTION OF THE DRAWINGS

FIG. 1 is a conceptual diagram regarding one embodiment of a power distribution cable asset management system according to the present disclosure.

FIG. 2 is a conceptual diagram regarding detailed configuration of a management unit illustrated in FIG. 1.

FIG. 3 is a flowchart illustrating a process of managing by assigning a line health grade according to a line health index in the power distribution cable asset management system according to the present disclosure.

FIG. 4 is a conceptual diagram regarding detailed configuration of a sensor unit illustrated in FIG. 1.

FIG. 5 is a conceptual diagram regarding detailed configuration of a terminal unit illustrated in FIG. 1.

### DETAILED DESCRIPTION

Hereinafter, exemplary embodiments of the present disclosure will be described in detail with reference to the accompanying drawings. However, the present disclosure is not limited to the exemplary embodiments to be described below and may be specified as other aspects. On the contrary, the embodiments introduced herein are provided to make the disclosed content thorough and complete, and sufficiently transfer the technical teachings of the present disclosure to those skilled in the art. Like reference numerals indicate like constituent elements throughout the specification.

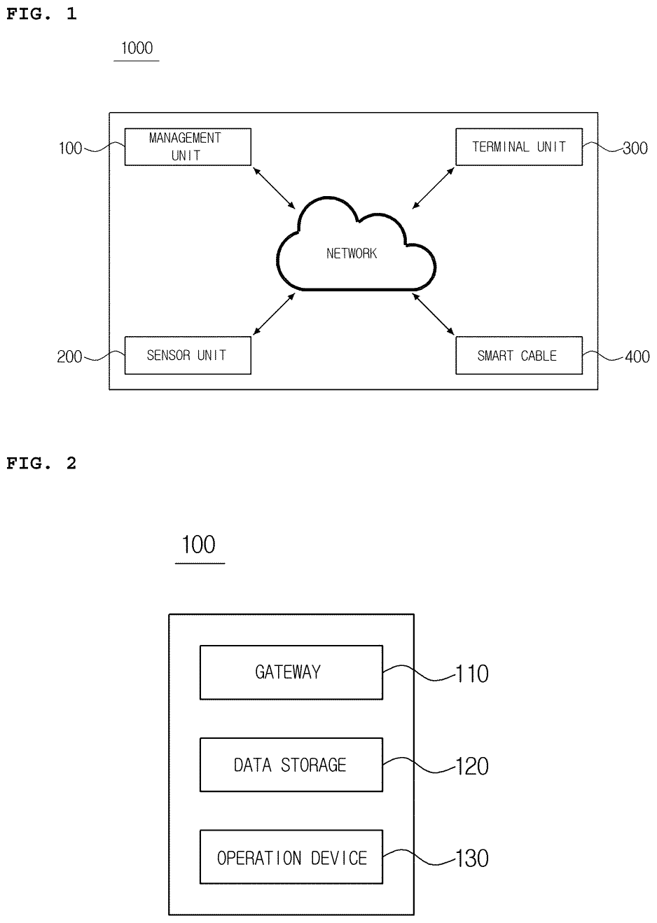

FIG. 1 is a conceptual diagram regarding one embodiment of a power distribution cable asset management system according to the present disclosure.

As illustrated in FIG. 1, a power distribution cable asset management system 1000 according to the present disclosure includes a management unit 100 that stores and manages various information on a line of an electric power supply system through a power distribution cable, a sensor unit 200 that collects various information from the line of the electric power supply system and transmits the collected information to the management unit 100, a terminal unit 300 that enables a manager to recognize a cable of the line and to view information stored and managed in the management unit 100 regarding the recognized cable, a smart cable 400 that forms the line, is recognizable through the terminal unit 300, and has information stored and managed through the management unit 100, and the like, and the management unit 100, the sensor unit 200, and the terminal unit 300 are connected through a network provided with wired or wireless communication network so that transmission and reception of information is possible.

FIG. 2 is a conceptual diagram regarding detailed configuration of a management unit illustrated in FIG. 1.

As illustrated in FIG. 2, the management unit 100 includes a gateway 110 provided with a receiver that receives various information on a line collected from the sensor unit 200 through a network, a data storage 120 that stores information collected through the gateway 110, and an operation device 130 that calculates a line health index of the line from the information stored in the data storage 120.

Here, the receiver provided in the gateway 110 may be matched 1:1 with various sensors provided in the sensor unit 200, and, in a possible case, one receiver may be matched with multiple sensors.

In addition, the data storage 120 may further store information on manufacturing and distribution process of a power distribution cable, and information on laying and operation environment in addition to the information collected through the sensor unit 200.

Here, the information on the manufacturing process of the power distribution cable may include product name, structure, allowable voltage, allowable transmission amount, allowable current, allowable temperature, total weight, specification, quantity, color, certification details, manufacturing date, and the like of the cable, and the information on the distribution process of the power distribution cable may include transport information, warehousing date, shipping date, supplier, presence of inventory, inventory amount, inventory storage location information, and the like.

In addition, the information on the laying environment of the power distribution cable may include information on a method in which the power distribution cable is laid, presence of a conduit, or degree of bending, surrounding temperature and humidity, and the like, and the information on the operation environment of the power distribution cable may include information on load characteristic of the line, failure rate, and the like.

In particular, the operation device 130 may calculate a line health index of the power distribution cable forming the line based on various information on the line stored in the data storage 120, and after calculating the line health index, may manage the line health grade of the power distribution cable by classifying the line health grade into, for example, good, caution, warning, and serious according to the calculated line health index.

Specifically, in the data storage 120, manufacturing process information, distribution process information, laying and operation environment information, information collected through the sensor unit 200, and the like are stored and managed as big data by position and time of the line, and the operation device 130 acquires statistics regarding causes of replacement of a cable by position of the line by utilizing the big data and sets a weight by failure cause item according to frequency of failure cause based on the statistics.

For example, in case where among 10 power distribution cables replaced at a specific position of a line, 7 cases are due to lifespan and 3 cases are due to insulation layer deterioration, a weight of lifespan among failure cause items of the power distribution cable is 0.7, and a weight of insulation layer deterioration is 0.3. In addition, a score regarding lifespan of the power distribution cable may be calculated as 97 points for 5 years or less of service life, 95 points for 5 to 10 years, 91 points for 10 to 15 years, and the like and a score regarding insulation layer deterioration may be calculated as 95 points for thermal imaging temperature of 30 to 40° C., 90 points for 40 to 50° C., 85 points for 50 to 60° C., and the like, and a line health index may be obtained by summing values obtained by multiplying the scores for each item by their respective weights.

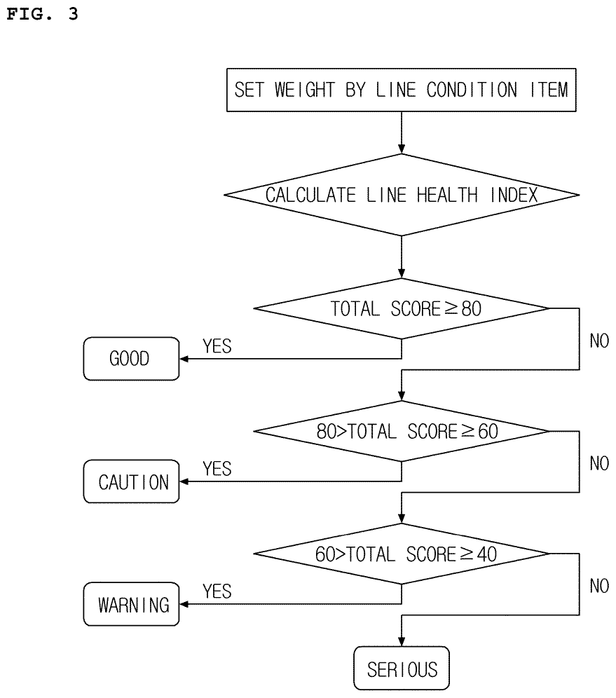

FIG. 3 is a flowchart illustrating a process of managing by granting a line health grade according to a line health index in the power distribution cable asset management system according to the present disclosure.

As illustrated in FIG. 3, in case where a line health index determined by the data storage 120 and the operation device 130 by line position is 80 points or more, a good grade may be assigned, in case of 60 to 80 points, a caution grade may be assigned, in case of 40 to 60 points, a warning grade may be assigned, and in case of less than 40 points, a serious grade may be assigned so that management is possible.

For example, the good grade is a grade requiring stable management by intermittent monitoring in consideration of line operation environment and cable condition, the caution grade is a grade requiring stable management by real-time online monitoring in consideration of line operation environment and cable condition, the warning grade is a grade requiring inspection of an offline line condition, and the serious grade may be a grade requiring immediate line precise diagnosis and replacement.

Accordingly, the power distribution cable asset management system 1000 according to the present disclosure exhibits an excellent effect of enabling efficient and accurate decision-making (judgments) regarding line diagnosis, replacement, and the like by calculating a line health index according to a weight by replacement cause item calculated based on statistics regarding replacement of a line by line position.

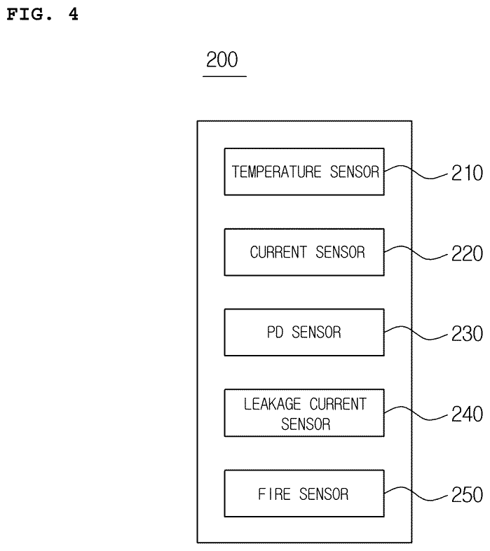

FIG. 4 is a conceptual diagram regarding detailed configuration of a sensor unit illustrated in FIG. 1.

As illustrated in FIG. 4, the sensor unit 200 may measure temperature, load current, insulation resistance, VLF (Very Low Frequency) tan delta value, PD (Partial Discharge) value, dielectric tangent value, harmonic value, and the like of a power distribution cable, and may include various sensors for measuring the same, for example, a temperature sensor 210, a current sensor 220, a PD sensor 230, a leakage current sensor 240, a fire sensor 250, and the like.

The temperature sensor 210 may be disposed at a local heating portion including a joint portion of the power distribution cable, does not require a separate power source by using an energy harvesting technology converting a magnetic field of the power distribution cable into electric power, and may transmit a signal to a receiver provided in the gateway 110 through Zigbee wireless communication technology. Further, the temperature sensor 210 may measure temperature precisely even when local heating occurs at a portion vulnerable to heating, with a multi-point temperature sensor of three or more points spaced apart at 120° intervals around a power distribution cable.

In addition, the current sensor 220 may be a Rogowski coil type sensor, the PD sensor 230 may be an SI (signal-inductive) capacitive type sensor, the leakage current sensor 240 may be a cable resistive leakage current sensor, and the fire sensor 250 may be an electrochemical CO (carbon monoxide) detection sensor.

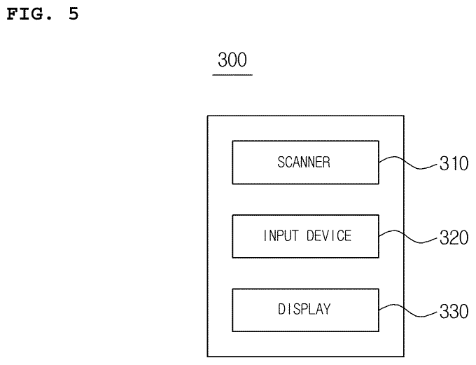

FIG. 5 is a conceptual diagram regarding detailed configuration of a terminal unit illustrated in FIG. 1.

As illustrated in FIG. 5, the terminal unit 300 may include a scanner 310 capable of scanning a pattern printed on a surface to identify a smart cable 400, an input device 320 that inputs contents diagnosed offline regarding a line by a manager, and a display 330 that displays information on the smart cable 400 scanned by the scanner 310, a line health index, a line health grade, etc. and the like.

Specifically, a line health grade assigned by the operation device 130 of the management unit 100 for a power distribution cable at a specific position of a line is displayed on the display 330 of the terminal unit 300, and a manager may scan a pattern printed to identify the cable on a surface of the power distribution cable through the scanner 310 of the terminal unit 300, recognize the scanned pattern, and perform offline inspection or replacement of the power distribution cable based on the information and the line health grade of the power distribution cable displayed on the display 330.

Meanwhile, as the power distribution cable, the smart cable 400 has a pattern printed on an outer surface thereof that is capable of identifying the power distribution cable, and when the manager scans the pattern through the scanner 310 of the terminal unit 300, information on the power distribution cable recognized according to the scanned pattern is provided from the data storage 120 of the management unit 100 and displayed on the display 330 of the terminal unit 300.

In addition, information on the power distribution cable stored in the data storage 120 of the management unit 100 may be automatically updated by receiving information from the sensor unit 200, or may be manually updated by a manager through the input device 320 of the terminal unit 300.

In particular, since the outer surface of the smart cable 400 on which the pattern is printed is a curved surface and the material is a material with low permeability of general ink, drying speed of ink is slow and there are many cases where ink blurs or a state of printed matter is of poor quality. Therefore, by adopting a printing method of printing with ultraviolet (UV) curing ink and then instantly curing through ultraviolet (UV) curing, drying speed of ink may be reduced and quality of printed matter may be improved.

In addition, the printed pattern may form a two-dimensional code, for example, a data matrix code or a QR code according to an ISO/IEC international standard. In the conventional DoT pattern in which the same pattern is repeatedly attached in a longitudinal direction of a cable, printing defect is likely to occur due to cable rotation, and there may occur a problem that probability of damage at laying is high, but according to the pattern of the embodiment of the present disclosure, there is an advantage of overcoming the conventional problem as described above, improving printing quality, and securing visibility.

While the present specification has been described above with reference to the exemplary embodiments of the present disclosure, it may be understood by those skilled in the art that the present disclosure may be variously modified and changed without departing from the spirit and scope of the present disclosure disclosed in the claims. Therefore, it should be understood that any modified embodiment that essentially includes the constituent elements of the claims of the present disclosure is included in the technical scope of the present disclosure.

1. A power distribution cable asset management system, comprising:
a management unit configured to store and manage information on a line including a power distribution cable; and
a sensor unit configured to collect information from the line and transmits the collected information to the management unit,
wherein the management unit calculates a line health index of the power distribution cable included in the line based on the information on the line.

2. The power distribution cable asset management system of claim 1, wherein the management unit comprises:
a gateway configured to receive information on the line collected from the sensor unit;
a data storage configured to store the information collected through the gateway; and
an operation device configured to calculate a line health index of the power distribution cable included in the line from the information stored in the data storage.

3. The power distribution cable asset management system of claim 2, wherein the information stored in the data storage comprises at least one selected from a group consisting of manufacturing process information of the power distribution cable, distribution process information of the power distribution cable, laying environment information of the power distribution cable, and operation environment information of the power distribution cable, in addition to the information collected through the gateway.

4. The power distribution cable asset management system of claim 3, wherein the manufacturing process information comprises at least one selected from a group consisting of product name of the power distribution cable, structure of the power distribution cable, allowable voltage of the power distribution cable, allowable transmission amount of the power distribution cable, allowable current of the power distribution cable, allowable temperature of the power distribution cable, total weight of the power distribution cable, specification of the power distribution cable, quantity of the power distribution cable, color of the power distribution cable, certification details of the power distribution cable, and manufacturing date of the power distribution cable,
wherein the distribution process information comprises at least one selected from a group consisting of transport information of the power distribution cable, warehousing date of the power distribution cable, shipping date of the power distribution cable, supplier of the power distribution cable, presence of inventory of the power distribution cable, inventory amount of the power distribution cable, and inventory storage location information of the power distribution cable,
wherein the laying environment information comprises at least one selected from a group consisting of a laying method of the power distribution cable, presence of a conduit of the power distribution cable, degree of bending of the power distribution cable, surrounding temperature of the power distribution cable, and surrounding humidity of the power distribution cable, and
wherein the operation environment information comprises at least one selected from a group consisting of load characteristic of the line and failure rate of the line.

5. The power distribution cable asset management system of claim 3, wherein the operation device:
acquires statistics regarding replacement causes of one or more power distribution cables by line position by utilizing the information stored in the data storage as big data;
sets a weight by failure cause item according to frequency of failure causes of the power distribution cable based on the statistics; and
obtains a line health index by calculating scores by replacement cause item of the one or more power distribution cables, then summing values obtained by multiplying the scores by the weights.

6. The power distribution cable asset management system of claim 5, wherein the operation device assigns a line health grade as good, caution, warning, and serious in descending order of the line health index.

7. The power distribution cable asset management system of claim 1, wherein the sensor unit comprises at least one selected from a group consisting of a temperature sensor, a current sensor, a PD (Partial Discharge) sensor, a leakage current sensor, and a fire sensor.

8. The power distribution cable asset management system of claim 1, further comprising:
a terminal unit configured to enable a manager to recognize a power distribution cable of the line and to view information stored and managed in the management unit regarding the recognized power distribution cable.

9. The power distribution cable asset management system of claim 8, wherein the terminal unit comprises:
a scanner capable of scanning a pattern printed on a surface of the power distribution cable to identify the power distribution cable;
an input device through which a manager inputs contents of offline diagnosis regarding the line; and
a display displaying information on the power distribution cable scanned by the scanner and a line health index.

10. The power distribution cable asset management system of claim 9, wherein the power distribution cable comprises a smart cable having a pattern printed on an outer surface thereof capable of identifying the power distribution cable.

11. The power distribution cable asset management system of claim 10, wherein the information on the power distribution cable stored in the management unit is automatically updated by receiving information from the sensor unit, or is manually updated by the manager through the input device of the terminal unit, and when the manager scans the pattern with the scanner of the terminal unit, information on the power distribution cable recognized according to the scanned pattern is provided from the management unit and displayed on the display of the terminal unit.

12. The power distribution cable asset management system of claim 10, wherein the pattern is printed with ultraviolet (UV) curing ink cured by ultraviolet irradiation, and forms a two-dimensional code.
